(19) United States
(12) Patent Application Publication
(10) Pub. No.: US 2024/0222304 A1
(43) Pub. Date: Jul. 4, 2024

(54) METHODS AND APPARATUS TO REDUCE SOLDER BUMP BRIDGING BETWEEN TWO SUBSTRATES

(71) Applicant: Intel Corporation, Santa Clara, CA (US)

(72) Inventors: Bohan Shan, Chandler, AZ (US); Jiaqi Wu, Chandler, AZ (US); Haobo Chen, Chandler, AZ (US); Srinivas Pietambaram, Chandler, AZ (US); Bai Nie, Chandler, AZ (US); Gang Duan, Chandler, AZ (US); Kyle Arrington, Gilbert, AZ (US); Ziyin Lin, Chandler, AZ (US); Hongxia Feng, Chandler, AZ (US); Yiqun Bai, Chandler, AZ (US); Xiaoying Guo, Chandler, AZ (US); Dingying Xu, Chandler, AZ (US)

(21) Appl. No.: 18/148,148

(22) Filed: Dec. 29, 2022

(51) Int. Cl. H01L 23/00; H01L 23/538

(52) U.S. Cl. CPC H01L 24/16; H01L 23/538; H01L 24/03; H01L 24/05; H01L 24/08; H01L 24/09; H01L 24/11; H01L 24/13; H01L 24/17; H01L 24/81; H01L 25/16

(57) ABSTRACT

Methods and apparatus to reduce solder bump bridging between two substrates. An apparatus includes a first substrate including a first bump and a second bump spaced apart from the first bump, the first bump including a first base, the second bump including a second base; and a second substrate including a third bump and a fourth bump spaced apart from the third bump, the third bump including a third base, the fourth bump including a fourth base, the first base electrically coupled to the third base by first solder, the second base electrically coupled to the fourth base by second solder, the first solder having a first volume, the second solder having a second volume, the first volume less than the second volume.

### FIELD OF THE DISCLOSURE

This disclosure relates generally to integrated circuits and, more particularly, to methods and apparatus to reduce solder bump bridging between two substrates.

### BACKGROUND

In many integrated circuit packages, one or more semiconductor dies are mechanically and electrically coupled to an underlying package substrate. Frequently, the coupling of a die to an underlying substrate is achieved by aligning and connecting metal bumps fabricated on a surface of the die with corresponding pads and/or bumps on a facing surface of the package substrate by thermally compressing the die and package substrate together. Due to the decrease in die size, substrate dimension, and package complexity, warpage commonly occurs during the thermal compression bonding.

### BRIEF DESCRIPTION OF THE DRAWINGS

FIG. 1 illustrates an example integrated circuit (IC) package that includes two example semiconductor dies electrically coupled to a package substrate that is electrically coupled to a circuit board.

FIG. 2 illustrates an example mode of warpage between a semiconductor die and an underlying substrate to which the die is to be attached.

FIG. 3 illustrates an example solder bump bridging between two adjacent bump connections after thermal compression bonding is completed.

FIG. 4 illustrates different stages during a conventional fabrication process to provide bumps on a substrate.

FIG. 5 illustrates different stages during an example fabrication process to provide bumps on a substrate in accordance with teachings disclosed herein.

FIG. 6 illustrates different examples stages during another example fabrication process to provide bumps on a substrate in accordance with teachings disclosed herein.

FIG. 7 illustrates different examples stages during another example fabrication process to provide bumps on a substrate in accordance with teachings disclosed herein.

FIG. 8 illustrates conventional bumps before thermal compression bonding and conventional bumps after thermal compression bonding.

FIG. 9 illustrates an example of bumps before thermal compression bonding and bumps after thermal compression bonding in accordance with teachings disclosed herein.

FIG. 10 is an example substrate with an arrangement of bumps.

FIG. 11 is a flowchart illustrating an example method of manufacturing a substrate with bumps of different base heights in accordance with teachings disclosed herein.

FIG. 12 is a top view of a wafer including dies that may be included in an IC package constructed in accordance with teachings disclosed herein.

FIG. 13 is a cross-sectional side view of an IC device that may be included in an IC package constructed in accordance with teachings disclosed herein.

FIG. 14 is a cross-sectional side view of an IC device assembly that may include an IC package constructed in accordance with teachings disclosed herein.

FIG. 15 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device. “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third.” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

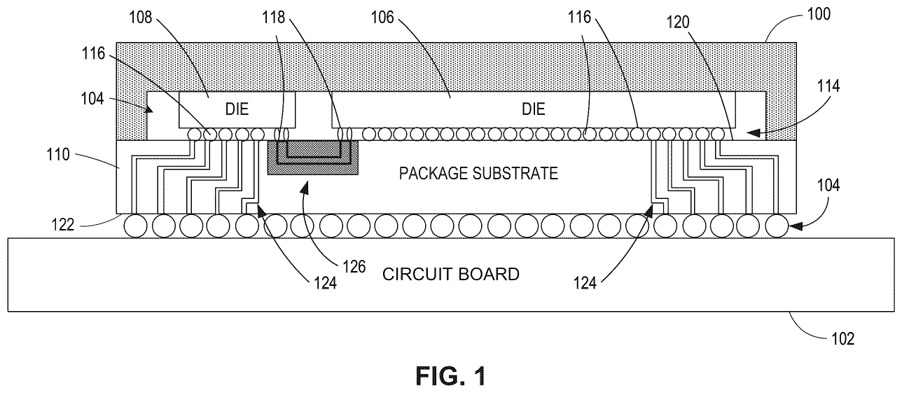

FIG. 1 illustrates an example integrated circuit (IC) package 100 that is electrically coupled to a circuit board 102 via an array of bumps or balls 104 (e.g., a ball grid array). In some examples, the IC package 100 may include pins and/or pads, in addition to or instead of the balls 104, to enable the electrical coupling of the IC package 100 to the circuit board 102. As used herein, bumps, balls, pins, and pads are generally referred to as contacts. In this example, the IC package 100 includes two semiconductor (e.g., silicon) dies 106, 108 that are mounted to a package substrate 110 and enclosed by a package lid or mold compound 112. While the example IC package 100 of FIG. 1 includes two dies 106, 108, in other examples, the IC package 100 may have only one die or more than two dies.

As shown in the illustrated example, each of the dies 106, 108 is electrically and mechanically coupled to the package substrate 110 via corresponding arrays of bumps 114. The electrical connections between the dies 106, 108 and the package substrate 110 (e.g., the bumps 114) are sometimes referred to as first level interconnects. By contrast, the electrical connections between the IC package 100 and the circuit board 102 (e.g., the balls 104) are sometimes referred to as second level interconnects. In some examples, one or both of the dies 106, 108 may be stacked on top of one or more other dies. In such examples, the dies 106, 108 are coupled to the underlying die through a first set of first level interconnects and the underlying die may be connected to the package substrate 110 via a separate set of first level interconnects associated with the underlying die. Thus, as used herein, first level interconnects refer to bumps between a die and a package substrate or a die and an underlying die.

As shown in FIG. 1, the bumps 114 of the first level interconnects include two different types of bumps corresponding to core bumps 116 and bridge bumps 118. As used herein, core bumps 116 refer to bumps on the dies 106, 108 through which electrical signals pass between the dies 106, 108 and components external to the IC package 100. Thus, as shown in the illustrated example, the core bumps 116 physically connected to the inner surface 120 of the package substrate 110 are electrically coupled to the balls 104 on the external surface 122 of the package substrate 110 via internal interconnects or traces 124 within the package substrate 110. As used herein, bridge bumps 118 refer to bumps on the dies 106, 108 through which electrical signals pass between different ones of the dies 106, 108 within the IC package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. Regardless of context, core or bridge, as used herein the term bump refers to a chip-to-chip interconnect feature that includes, but is not limited to, a protruding metal base or pillar that includes solder material on a distal end of the metal base. In some implementations, the metal base includes a copper pillar with solder material on the copper pillar.

The bumps 114 associated with the first level interconnects are fabricated through a series of different processes that can lead to potential defects when an IC package such as the IC package 100 of FIG. 1 is assembled. In particular, the bumps 114 are initially formed through a lithographic process by which a dry film resist is applied to the surface where the bumps 114 are to be formed. The dry film resist is patterned with openings corresponding to the locations of the individual bumps and then a plating process is performed to fill the openings with metal that is to serve as the bumps 114. Often, the metal used for the plating of the bumps 114 include a layer of copper that is in electrical contact with metal interconnects within the substrate onto which the bumps 114 are being formed. Thereafter, a nickel barrier layer is added onto the copper and then a layer of solder (such as tin) is added onto the nickel.

A potential source of defects in bumps 114 of the first level interconnects can arise from warpage in the dies 106, 108 and/or the underlying package substrate 110. Warpage can arise during the fabrication of each of the dies 106, 108 and/or the package substrate 110 due to mismatches in the coefficient of thermal expansion (CTE) of the materials in such substrates (as used herein, the term “substrate” generically refers to both dies and package substrates) when heated and/or due to copper density variation during the metal plating process. Warpage can also arise during the thermocompression bonding (TCB) process during which the dies 106, 108 and/or the package substrate 110 are heated and pressed together to enable corresponding bumps and/or pads (e.g., contacts) on the facing surfaces to bond.

Ideally, each of the bumps and/or pads on the facing surfaces of the dies 106, 108 and the package substrate 110 will be co-planar so that all corresponding bumps and/or pads contact one another at the same time when they are pressed together. However, warpage in the dies 106, 108 and/or the package substrate 110 result in some bumps and/or pads being higher or jutting outward relative to the average position of the bumps and/or pads while other bumps are lower or recessed relative to the average position of the bumps and/or pads. Due to this lack of co-planarity, when the dies 106, 108 are attached to the package substrate 110 during the TCB process, the bumps on the dies 106, 108 and/or package substrate 110 that jut outward relative to other bumps will be the first to contact the mating bumps and/or pads on the mating surface while other bumps on the dies 106, 108 and/or package substrate 110 will need to be pressed closer together before bonding is possible. The force required to ensure all bumps are properly bonded can cause the bumps that jut outward to be crushed in a manner that can spread the solder of the crushed bump towards adjacent bumps, thereby resulting in undesirable bridging of adjacent bumps. The likelihood of this problem occurring increases as bump pitches scale downward because there is a shorter distance the solder must travel when deformed before an undesirable bridge develops. Furthermore, the bumps and/or pads on facings surfaces of the dies 106, 108 and the package substrate 110 that are farthest apart (because they are recessed relative to other bumps) may not be pressed sufficiently close to produce a reliable bond during the TCB process.

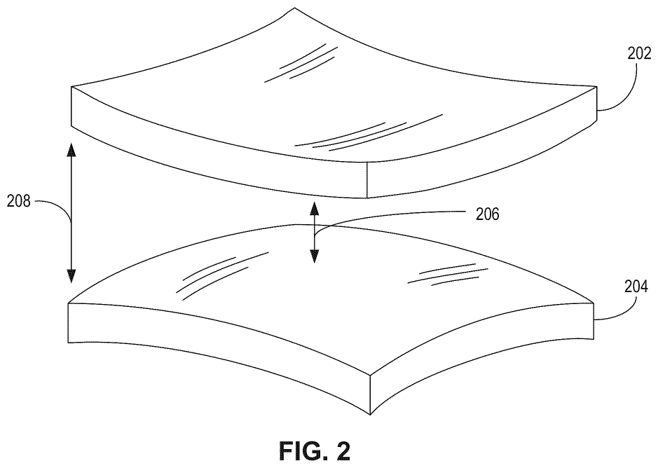

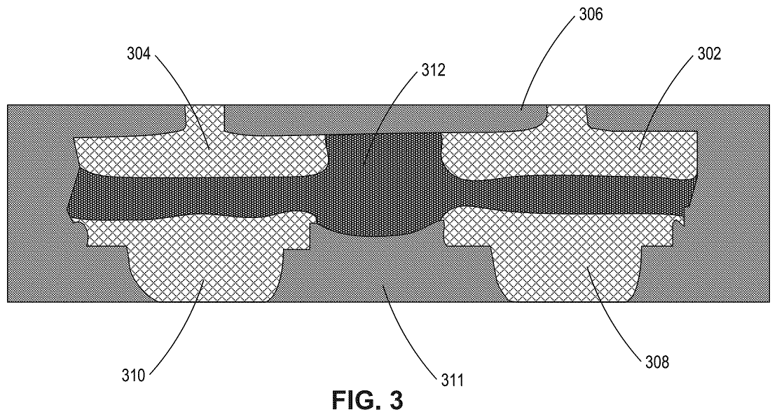

A common way in which two substrates to be connected (e.g., a die and a package substrate (or other underlying die)) can warp during the TCB process is by the outer edges of both substrates bending or curving away from one another as illustrated in FIG. 2. That is, as a die 202 is pressed against an underlying substrate 204, the facing surfaces of the components will warp to form convex-like surfaces. The warpage in the illustrated example of FIG. 2 is exaggerated for purposes of explanation. As shown, the center of the die 202 is a first distance 206 away from the substrate 204, whereas the outer edge of the die 202 is a second distance 208 that is significantly greater than the first distance 206. Warpage as demonstrated in FIG. 2 is likely to result in crushed bumps near the center of the die 202 and/or the substrate 204 and bumps near the outer edge that do not bond properly with corresponding bumps and/or pads on the mating surface. More particularly, as discussed further below, the bumps include a metal base with solder coupled to a distal or outward facing end that electrically couples the metal base to a corresponding bump (or other contact) on the interfacing substrate. Typically, the metal base is a stiffer material, than the solder, which does not melt during the thermal compression bonding process, whereas the solder will melt. As such, the concern for bumps near the center of the die 202 in FIG. 2 being crushed is, more particularly, a concern with the solder of such being crushed. As the solder is crushed between the two metal bases on the facing substrates to be coupled, the solder can be forced laterally away from the distal ends of the metal bases thereby giving rise to the possibility of creating a short circuit of solder bridge with an adjacent bump as represented in FIG. 3, which is based on an SEM image of actual bumps. In particular, as shown in FIG. 3, first and second metal bases 302, 304 associated with a first substrate 306 are electrically coupled to corresponding third and fourth metal bases 308, 310 associated with a second substrate 311 via solder 312. However, as shown in FIG. 3, due to solder bridging, the solder 312 extends continuously between the two pairs of bases 302, 304, 308, 310 thereby establishing a short circuit between the adjacent bumps. The solder bridging shown in FIG. 3 arises due to the relatively small distance (e.g., the first distance 206 of FIG. 2) between the bases 302, 304, 308, 310 resulting in a relatively high compression force between the substrates 306, 311 during the thermal compression bonding process. The high compression force applied to the bumps in FIG. 3 was sufficient to force the solder 312 to leak lateral from at least one of the bumps until the solder 312 associated with both pairs of bumps was combined into the solder bridge.

As discussed more fully below, examples disclosed herein reduce the effects of non-coplanar bumps that can arise from substrate warpage by fabricating the bumps with different metal and solder heights (e.g., thicknesses) that vary spatially (e.g., differ at different locations) on at least one of the substrates to compensate for expected warpage across the same area. In the illustrated example of FIG. 2, bumps located near the center of the die 202 and associated substrate 204 contain taller metal bases with a reduced amount of solder relative to other bumps closer to the outer edge of the die 202. Thus, as the substrates (e.g., the die 202 and the package substrate 204) are compressed together, the reduced amount of solder on the taller bases reduces the amount of solder that may be forced laterally, thereby reducing the likelihood of the solder bridging with adjacent bumps. In some examples, the increased height of the taller bases is offset by a reduced height associated with the reduced amount of solder on the taller bases so that all bumps have a substantially consistent overall height (including both the base and the solder). However, in other examples, the combined height of the taller bases with the associated solder is greater than the combined height of the shorter bases with the associated solder. Thus, as used herein, the phrase “taller bumps” is used herein to refer to bumps that have taller bases than other bumps on a substrate regardless of whether the overall height of the bump (when the solder is also taken into account) exceeds the height of the other bumps. Likewise, as used herein, the phrase “shorter bumps” is used herein to refer to bumps that have shorter bases than the bases of the “taller bumps” on the substrate regardless of whether the overall height of the bump (when the solder is also taken into account) is less than the height of the “taller bumps.” “Shorter bumps” are also referred to herein as “regular bumps.”

Further, the taller bumps in examples disclosed herein act as pillars or mechanical stops to prevent the shorter bumps from being compressed too close together so as to crush the greater amount of solder associated with such shorter bumps. In other words, the taller bumps provide mechanical support to maintain a gap between the two substrates to avoid crushing shorter bumps at locations between the substrates that are closer together (e.g., near the center in FIG. 2 due to warpage) while still allowing adequate force to be applied to other locations of the substrate that are father apart (e.g., near the outer edges in FIG. 2) to bring them sufficiently close to establish reliable bonds between interfacing solder bumps. In some examples, the taller bumps with taller bases and the bumps with shorter bases may be interspersed between each other. That is, in some examples, not all bumps with taller bases (e.g., the taller bumps) are near the center of the substrates and not all bumps with shorter bases (e.g., the shorter bumps) are near the outer edge at the substrates. However, in some instances, the taller bumps can be more concentrated at the center (or any other region) of the substrate as described above. In other examples, the taller bumps can be distributed relatively evenly across an area of the substrate with the taller bumps being interspersed among the shorter bumps that are also distributed across the same area. In some such examples, the taller bumps are more sparsely distributed across the area than the shorter bumps. Thus, in some examples, individual ones of the taller bumps are surrounded by shorter bumps such that the nearest adjacent bumps to ones of the taller bumps is a shorter bump (rather than another taller bump).

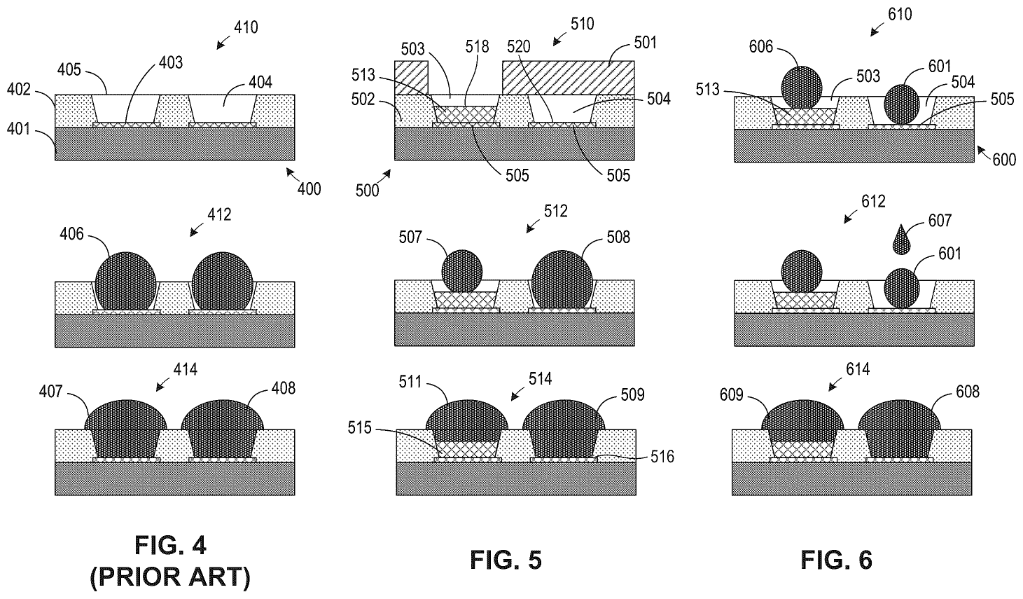

FIG. 4 illustrates different stages of fabrication 410, 412, 414 during a conventional fabrication process of using micro balls 406 to produce bumps on a substrate 400 such as a semiconductor die (e.g., any one of the dies 106, 108, 202 of FIGS. 1 and/or 2) and/or a package substrate (e.g., any one of the package substrates 110, 204 of FIGS. 1 and/or 2). At the stage of fabrication 410 shown at the top of FIG. 4, the substrate 400 includes a dielectric layer 401 that supports a thin layer of metal plating 403 at the bottom of openings 404 within a solder resist 402 deposited across the surface of the dielectric layer 401. In some examples, the thin layer of metal plating 403 is copper (Cu). In some examples, the thin layer of metal plating 403 is electrically connected to metal vias and/or other metal interconnects (not shown for purposes of simplicity) within the dielectric layer 401. The stage of fabrication 412 represented by the middle of FIG. 4 represents the placing micro balls 406 in openings 404 in contact with the thin layer of metal plating 403. The stage of fabrication 414 at the bottom of FIG. 4 represents the substrate 400 following a reflow process in which the micro balls 406 are heated above their melting point to produce the final shape of the bumps 407, 408.

FIG. 5 illustrates different stages of fabrication 510, 512, 514 during a fabrication process that includes using micro balls 507, 508 to produce bumps with taller bases than other bump bases on a substrate 500 such as a semiconductor die (e.g., any one of the dies 106, 108, 202 of FIGS. 1 and/or 2) and/or a package substrate (e.g., any one of the package substrates 110, 204 of FIGS. 1 and/or 2). At the stage of fabrication 510 shown at the top of FIG. 5, the substrate 500 includes a dielectric layer 501 that supports a thin layer of metal plating 505 at the bottom of openings 503, 504 within a solder resist 502 deposited across the surface of the dielectric layer 501. In some examples, the thin layer of metal plating 505 is copper (Cu). In some examples, the thin layer of metal plating 505 is electrically connected to metal vias and/or other metal interconnects (not shown for purposes of simplicity) within the dielectric layer 501. The stage of fabrication 510 further includes a photoresist layer 506 patterned to cover openings 504 in the solder resist 502 while uncovering or exposed other openings 503 in the solder resist 502. At the stage of fabrication 510 shown at the top of FIG. 5, additional metal 513 is deposited on the thin layer of metal plating 505 in the opening 503 that remains uncovered by the photoresist layer 506 to provide a taller base 515. In the context of FIG. 5, the taller base 515 in the opening 503 includes the thin layer of metal plating 505 and the additional metal 513. By contrast, the base in the opening 504 is limited to the thin layer of metal plating 505.

The stage of fabrication 512 represented by the middle of FIG. 5 is after the removal of the photoresist layer 506 to expose all of the openings 503, 504 in the solder resist 502. Further, the stage of fabrication 512 represents the placing of a first micro ball 508 in the opening 504 that was previously covered by the photoresist layer 506 and depositing a second micro ball 507 in the opening 503 on the taller base 515. As shown in the illustrated example, the first micro ball 508 is in contact with the thin layer of metal plating 505 within the opening 504 and a second micro ball 507 is in contact with the taller base 515. In this example, the second micro ball 507 is smaller (e.g., has less volume) than the first micro ball 508. The stage of fabrication 514 at the bottom of FIG. 5 represents the substrate 500 following a reflow process in which the first (larger) micro ball 508 and the second (smaller) micro ball 507 are heated above their melting point to produce the final shape of the bumps 509, 511. In this example, because the example bump 511 includes a taller base 515 than the example bump 509, during the TCB process the taller base 515 provides mechanical support to protect the shorter bump (e.g., the bump 509 with a shorter base) from being crushed to potentially give rise to solder bridging. In other words, the taller base 515 protrudes farther from the underlying dielectric material than the base of the bump 509 and extends farther into and/or through the solder resist 502 than the base 516 (corresponding to the thin layer of metal plating 505) of the bump 509. As a result, the outer surface (e.g., distal face) 518 of the taller base 515 will be closer to a corresponding contact (e.g., bump) on an interfacing substrate than the outer surface (e.g., distal face) 520 of the shorter base 516. Furthermore, due to the smaller size of the second micro ball 507, the example bump 511 includes less solder than the example bump 509. As a result, under heavy compression, the risk of the solder associated with the taller bump 511 leaking towards an adjacent bump is reduced.

FIG. 6 illustrates different stages of fabrication 610, 612, 614 during another fabrication process that includes using micro balls 601, 606 to produce bumps with taller bases than other bump bases on a substrate 600 such as a semiconductor die (e.g., any one of the dies 106, 108, 202 of FIGS. 1 and/or 2) and/or a package substrate (e.g., any one of the package substrates 110, 204 of FIGS. 1 and/or 2). The example process illustrated in FIG. 6 mirrors the process shown in FIG. 5 through the stage of fabrication 510. The stage of fabrication 610 shown at the top of FIG. 6 picks up after the stage of fabrication 510 of FIG. 5. Accordingly, the same reference numbers used in FIG. 5 will be used for the same parts in FIG. 6.

The stage of fabrication 610 represented by the top of FIG. 6 represents placing a micro ball 601 in the opening 504 in contact with the thin layer of metal plating 505 and a micro ball 606 in contact with the taller base 515. In this example, both micro balls 601, 606 are approximately the same size (e.g., have approximately the same volume). The stage of fabrication 612 represented by the middle of FIG. 6 represents a solder paste 607 deposited on the micro ball 601 in the opening 504 associated with the short base (corresponding to the thin layer of metal plating 505). The solder paste 607 is deposited onto the micro ball 601 until the desired height is reached and/or a desired volume of solder is attained. In some examples, the solder paste 607 is applied by pin-dipping.

The stage of fabrication 614 at the bottom of FIG. 6 represents the substrate 600 following a reflow process in which the micro balls 601, 606 and the additional solder paste 607 are heated above their melting point to produce the final shape of the bumps 608, 609. In this example, because the example bump 609 includes a taller base 515 than the example bump 608, during the TCB process the taller base 515 provides mechanical support. Furthermore, the example bump 609 includes less solder than the example bump 608. As such, under heavy compression, the risk of the solder leaking towards a neighboring bump is reduced.

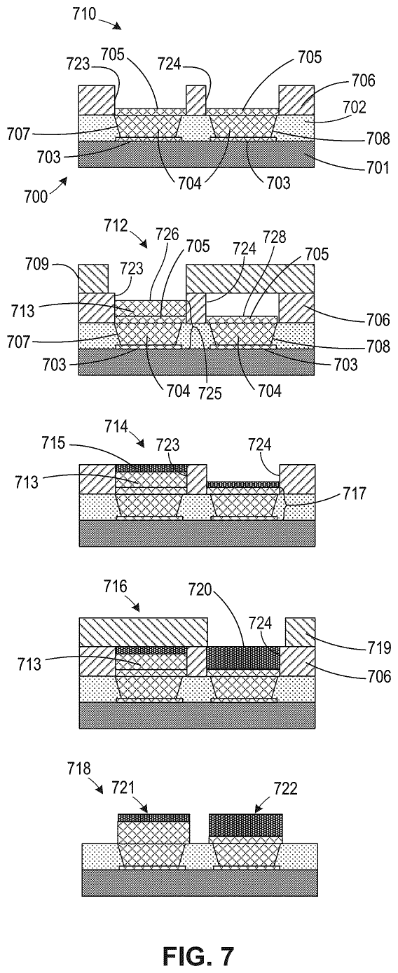

FIG. 7 illustrates different stages of fabrication 710, 712, 714, 716, 718 during a fabrication process that includes a double dual lithography process to produce bumps with taller bases than other bump bases on a substrate 700 such as a semiconductor die (e.g., any one of the dies 106, 108, 202 of FIGS. 1 and/or 2) and/or a package substrate (e.g., any one of the package substrates 110, 204 of FIGS. 1 and/or 2). At the stage of fabrication 710 shown at the top of FIG. 7, the substrate 700 includes a dielectric layer 701 that supports a first thin layer of metal plating 703 at the bottom of metal plating 704 in openings 707, 708 within a solder resist 702 deposited across the surface of the dielectric layer 701. At the stage of fabrication 710 shown at the top of FIG. 7, a first photoresist layer 706 is deposited across the solder resist 702 and patterned with openings 723, 724 aligned with the openings 707, 708 in the solder resist. In this example, a second thin layer of metal plating 705 is deposited over the metal plating 704 that fills the openings 707, 708 in the solder resist 702. In some examples, the first thin layer of metal plating 703 is copper (Cu). In some examples, the first thin layer of metal plating 703 is electrically connected to metal vias and/or other metal interconnects (not shown for purposes of simplicity) within the dielectric layer 701. In some examples, the metal plating 704 is copper (Cu). Likewise, in some examples, the second thin layer of metal plating 705 is copper (Cu). In some examples, the metal plating 704 within the solder resist openings 707, 708 and the additional metal that extends into the openings 723, 724 in the first photoresist layer 706 (e.g., the second thin layer of metal plating 705) are deposited in a single deposition (e.g., plating) process.

At the stage of fabrication 712 shown second from the top of FIG. 7, a second photoresist layer 709 is deposited over the first photoresist layer 706. The second photoresist layer 709, shown at the stage of fabrication 712, is patterned to cover openings 724 in the first photoresist layer 706 while uncovering or exposing other openings 723 in the first photoresist layer 706. At the stage of fabrication 712, additional metal 713 is deposited in the opening 723 which remains open or exposed through the second photoresist layer 709 to provide a taller base 725. In the context of FIG. 7, the taller base 725 includes the first thin layer of metal plating 703, the metal plating 704, the second thin layer of metal plating 705, and the additional metal 713. Further, the outer surface (e.g., distal face) 726 of the taller base 725 extends farther through the opening 723 than the outer surface (e.g., distal face) 728 of a shorter base 717 through the opening 724. In some examples, the additional metal 713 is deposited via metal plating. In some examples, the additional metal 713 includes copper (Cu).

At the stage of fabrication 714 shown in the middle of FIG. 7, the second photoresist layer 709 is removed to uncover the opening 724. The stage of fabrication 714 further represents the assembly after a thin solder layer 715 is deposited (e.g., plated) onto the taller base 725 within the opening 723 and the shorter base 717 within the opening 724. In the context of FIG. 7, the shorter base 717 includes the first thin layer of metal plating 703, the metal plating 704, and the second thin layer of metal plating 705. In some examples, the taller base 725 is approximately 1-50 microns taller than the shorter base 717 (e.g., at least 1 micron taller, at least 2 microns taller, at least 5 microns taller, at least 10 microns taller, at least 15 microns taller, at least 25 microns taller, etc.). At the stage of fabrication 716 shown second from the bottom of FIG. 7, a third photoresist layer 719 is deposited over the first photoresist layer 706. The third photoresist layer 719 is patterned to cover the bumps with the taller bases 725 while exposing the bumps with the shorter bases 717. At the stage of fabrication 716 additional solder 720 is deposited (e.g., plated) into the opening 724 in the first photoresist layer 706 through an opening in the third photoresist layer 719. In some examples, the additional solder 720, in combination with the initial thin solder 715, is approximately 1-50 microns taller than the thin solder layer 715 (e.g., at least 1 micron taller, at least 2 microns taller, at least 5 microns taller, at least 10 microns taller, at least 15 microns taller, at least 25 microns taller, etc.). In some examples, the additional solder 720 is deposited to provide a regular (shorter) bump 722 with a height (corresponding to a combined height of the shorter base 717, the initial thin solder layer 715, and the additional solder 720) that approximately matches the height of a taller base bump 721 (corresponding to a combined height of the taller base 725 and the thin solder layer 715). In some examples, the additional solder 720 is deposited with a thickness so that the regular bump 722 is shorter than the example taller base bump 721. That is, in some examples, the combined height of the shorter base 717, the thin soldering layer 715, and the additional solder 720 is less than a combined height of the taller base 725 and the thin solder layer 715. In some examples, the solder 720 is deposited with a thickness so that the regular bump is taller than the example taller base bump 721. That is, in some examples, the combined height of the shorter base 717, the thin soldering layer 715, and the additional solder 720 is greater than a combined height of the taller base 725 and the thin solder layer 715.

At the stage of fabrication 718 shown at the bottom of FIG. 7, the first photoresist layer 706 and the third photoresist layer are removed and the taller base bump 721 and a regular bump 722 remain. In some examples, the bumps 721, 722 undergo a subsequent reflow process that will reshape the solder to be more rounded before the bumps 721, 722 are mounted and/or attached to corresponding bumps or other contacts in a TCB process. In this example, because the example taller base bump 721 includes a taller base 725 than the regular bump 722, during the TCB process the taller base bump 721 provides mechanical support. As shown in FIG. 7, the taller base 725 has a different cross-sectional profile or shape than the cross-sectional profile or shape of the shorter base 717. In some examples, although the heights or thicknesses of the taller base 725 and the shorter base 717 differ, in some examples the diameter of the taller base 725 and the diameter of the shorter base 717 are approximately equal (e.g., the diameters of both bumps are designed to be equal). Furthermore, the example taller base bump 721 includes less solder than regular bump 722. As such, under heavy compression, the solder on the taller base 725 is less likely to spill towards the neighboring/adjacent bumps and the risk of solder bump bridging is reduced.

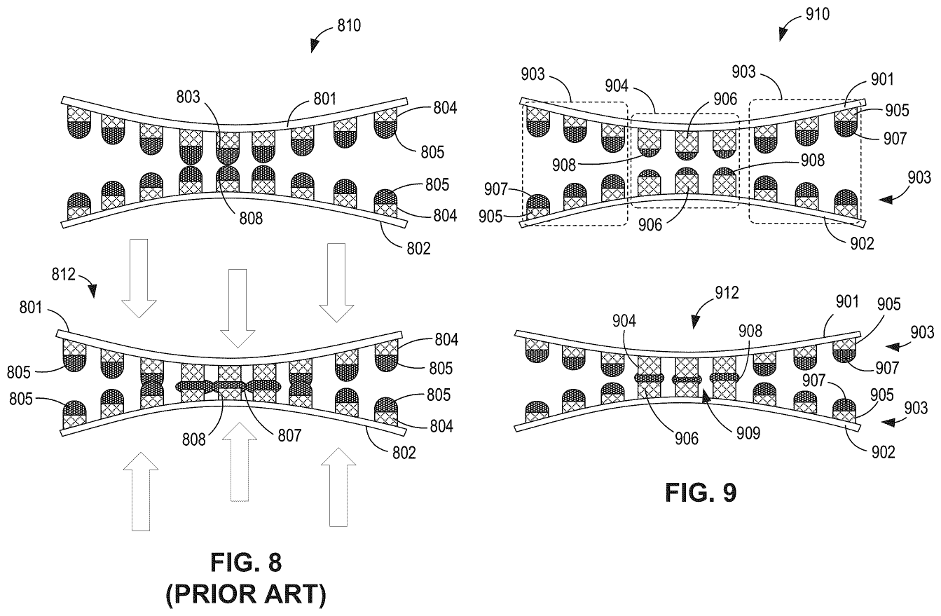

FIG. 8 illustrates an example of conventional bumps before TCB (top image 810) and the same bumps during TCB is completed (bottom image 812). Further, FIG. 8 illustrate a common way in which two substrates 801, 802 to be connected can warp during the TCB process, as described in further detail above in connection with FIG. 2. The two substrates 801, 802 include respective bumps 803, 808 which have bases 804 and associated solder 805 that are approximately the same size (e.g., same height and/or thickness) as between different ones of the bumps. Due to the warpage of the substrates 801, 802, the corresponding pairs of the bumps 803, 808 located near the center of the substrates 801, 802 are closer together than corresponding pairs of the bumps 803, 808 near the edge of the substrates 801, 802. During the TCB process, as represented by the bottom image 812 of FIG. 8, the bumps 803, 808 towards the center of the substrates 801, 802 are compressed together with force sufficient to crush the solder 805 on such bumps 803, 808 and cause the solder 806 to jut laterally outwards towards the adjacent bumps. In the illustrated examples, the amount of solder 805 results in a solder bump bridge 807 that establishes a short circuit between the adjacent pairs of interconnected bumps 803, 808. The high compression applied between the substrates 801, 802 is needed to establish a solder connection between corresponding pairs of the bumps 803, 808 near the outer edge of the substrates 801, 802.

FIG. 9 illustrates an example of two substrates including bumps with different sizes (heights and/or thicknesses) of bases before TCB and during the TCB process. As shown in FIG. 9, the first (upper) substrate 901 includes shorter (or regular) bumps 903 and taller bumps 904. In this example, the taller bumps 904 are located near the center of the substrate 901 and include taller bases 906 than the bases 905 of the shorter bumps 903 located near the outer edge of the substrate 901. Further, the shorter bumps 903 include a first amount of solder 907 that is greater than (e.g., greater volume) than a second amount of solder 908 on the taller bumps 904. In this example, the second (lower) substrate 902 similarly includes shorter (or regular) bumps 903 and taller bumps 904. As with the first substrate 901, the taller bumps 904 on the second substrate 902 are located near the center of the substrate 902 and include taller bases 906 than the bases 905 of the shorter bumps 903 located near the outer edge of the substrate 902. More particularly, in this example, the taller bumps 904 on the first and second substrates 901, 902 are aligned and the shorter bumps 903 on the first and second substrates 901, 902 are aligned. In other words, the taller bumps 904 and the shorter bumps 903 on the first substrate 901 face towards the taller bumps 904 and the shorter bumps on the second substrate 902. As shown in FIG. 9, the taller bumps 904 on the first substrate 901 are closer to the second substrate 902 than the shorter bumps 903 on the first substrate 901. Moreover, the outer surface or distal face of the taller bases 906 of the taller bumps 904 on the first substrate 901 would be closer to the second substrate 902 and/or closer to the correspond contacts (e.g., bumps) on the second substrate 902 than the outer surface or distal face of the shorter bumps 903 on the first substrate 901 are to the second substrate 902 (and/or corresponding contacts) even if the substrates 901, 902 were flat because the taller bases 906 protrude farther away from the first substrate 901 than the shorter bases 905 protrude away from the first substrate 901. In some examples, the location and spatial relationship of the shorter bumps 903 and the taller bumps 904 can differ from that which is shown in the illustrated example. For instance, in some examples, the taller bumps 904 are included towards the edge of the substrates 901, 902. In some examples, adjacent ones of the taller bumps 904 are separated by one or more of the shorter bumps 903.

During the TCB process, as represented in the bottom image 912 of FIG. 9, the substrates 901, 902 are compressed together. Due to the warpage of the substrates 901, 902, the bumps near the center of the substrates 901, 902 (e.g., the taller bumps 904) are closer together than the bumps near the outer edges of the substrates 901, 902 (e.g., the shorter bumps 903). Furthermore, due to the taller bumps 904 having taller bases 906, the corresponding pairs of taller bases 906 are even closer to one another than the bases 905 of the shorter bumps 903. As a result, when the substrates 901, 902 are compressed together, the solder 908 associated with the taller bumps 904 is likely to get crushed and extrude laterally toward adjacent bumps. However, in contrast to the solder bump bridge 807 shown in FIG. 8, the smaller amount of solder 908 on the taller bumps 904 in FIG. 9 reduces the extent to which the solder 908 juts lateral away from the corresponding bumps towards adjacent bumps. Thus, as shown in in the bottom image 912 of FIG. 9, there is a space 909 maintained between the solder 908 of the taller bumps 904 to avoid solder bump bridging. Furthermore, the rigid nature of the taller bases 906 (e.g., the bases 906 being more rigid than the solder 908) enables the interfacing taller bumps 904 to act as pillars or mechanical stops that maintain the two substrates 901, 902 a distance apart despite the relatively high compressive loads applied during the TCB process. In some examples, the distance at which the substrates 901, 902 are maintained apart due to the mechanical support provided by the taller bumps 904 is sufficient (e.g., small enough) to enable the shorter bumps 903 to be electrically coupled but insufficient (e.g., not too small) to cause the solder 907 associated with the shorter bumps 903 to be crushed and deformed, thereby giving rise to a solder bridge.

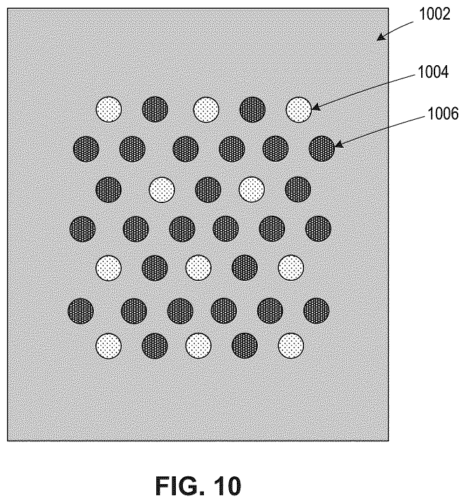

FIG. 10 is an example arrangement of taller bumps 1004 (identified by light shading in FIG. 10) and shorter bumps 1006 (identified by dark shading in FIG. 10) on a substrate 1002. The example arrangement includes the taller bumps 1004 spatially spread across a surface of the substrate 1002. As shown, adjacent ones of the taller bumps 1004 are separated by a shorter bump 1006 disposed therebetween. In some examples, more than one shorter bump 1006 is disposed between adjacent taller bumps 1004. In some examples, two or more taller bumps 1004 are directly adjacent with no shorter bumps disposed therebetween. That is, in some examples, the taller bumps 1004 may be arranged in clusters of multiple taller bumps 1004 with different clusters separated by one or more shorter bumps 1006. In some examples, all of the taller bumps 1004 are grouped together within an area in which there are no shorter bumps. In some examples, the taller bumps 1004 are interspersed between the shorter bumps 1006. In such examples, the shorter bumps 1006 are disposed outside the area containing the group of taller bumps 1004. Any other suitable arrangement of the taller bumps 1004 and the shorter bumps 1006 is possible. In the illustrated example, the taller bumps 1004 are evenly distributed across the area of the substrate 1002 including the bumps. In other examples, the taller bumps 1004 are concentrated (e.g., distributed with a higher density) in one area (e.g., towards the center of the substrate 1002) and less densely distributed (or entirely absent) in a second area (e.g., towards the outer edges). In some examples, the taller bumps 1004 are distributed across a first area of the substrate 1002 and the shorter bumps 1006 are distributed across a second area of the substrate 1002. In some examples, the second area of the substrate 1002 overlaps the first area of the substrate. Thus, in some examples, the taller bumps 1004 and the shorter bumps 1006 are distributed across the same area of the substrate 1002 with the taller bumps 1004 and the shorter bumps 1006 being interspersed among one another as shown in FIG. 10. In some examples, the first area of taller bumps 1004 is smaller than the second area of shorter bumps 1006 and the first area is entirely contained within the second area. For instance, in some examples, the taller bumps 1004 may be limited to a central area of the substrate 1002 with the shorter bumps 1006 surrounding the taller bumps 1004. In some such examples, the shorter bumps may additionally be interspersed within the central area circumscribing the taller bumps 1004. In some examples, the area(s) circumscribing the taller bumps 1004 do not overlap the area(s) circumscribing the shorter bumps 1006.

As discussed above, in some examples, the taller bumps are located on both substrates (e.g., a die and a package substrate (or other underlying die)). In some examples, only one of the two substrates being compressed together includes taller bumps with the other substrate including only shorter (regular) bumps. In some examples, the taller bumps on one substrate differ in height to the taller bumps on the interfacing substrate. In some examples, bumps are provided on only one of the two interfacing substrates with the second substrate including other types of contacts (e.g., metal pads) to which the bumps on the first substrate are connected using solder. In some such examples, at least some of the bumps on the first substrate are taller bumps constructed in accordance with teachings disclosed herein.

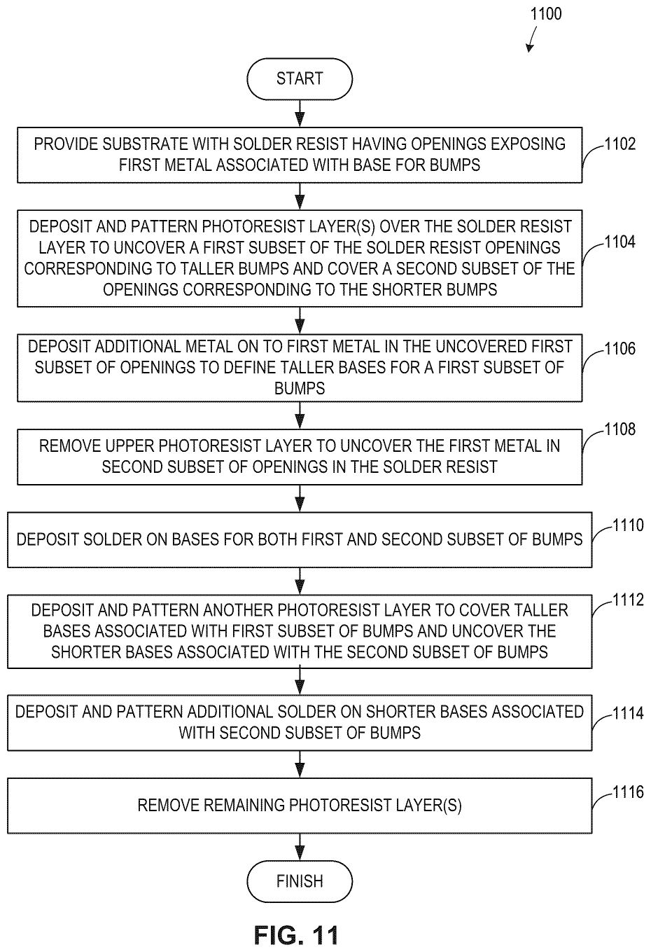

FIG. 11 is a flowchart illustrating an example method of manufacturing a substrate (e.g., the package substrate 110 of FIG. 1 and/or the die 108 of FIG. 1) with taller bumps and shorter bumps as described above in connection with FIGS. 5-7. Although the example method of manufacture is described with reference to the flowchart illustrated in FIG. 11, many other methods may alternatively be used. For example, the order of execution of the blocks may be changed, and/or some of the blocks described may be combined, divided, re-arranged, omitted, eliminated, and/or implemented in any other way.

The example process of FIG. 11 begins at block 1102, at which a substrate is provided with a solder resist having openings exposing first metal associated with based for bumps. In some examples, the first metal corresponds to the metal plating 505, 605, 703 in FIGS. 5-7, applied before the solder resist. In some examples, the solder resist with the associated openings corresponds to the solder resist 502, 702 and the associated openings 503, 504, 707, 708 described above in connection with FIGS. 5-7. In some examples, the first metal also includes the metal plating 704 added to fill the openings 707, 708 as in FIG. 7. At block 1104, a photoresist layer(s) is deposited and patterned over the solder resist to uncover or expose a first subset of the openings corresponding to taller bumps and to cover a second subset of openings corresponding to shorter bumps. In some examples, the photoresist layer(s) added at block 1104 correspond to the photoresist layer 506 described in connection with FIGS. 5 and/or 6. In other examples, the photoresist layer(s) added at block 1104 corresponds to both the first photoresist layer 706 and the second photoresist layer 709 described in connection with FIG. 7. As noted above, the first subset of the openings in the solder resist that are uncovered correspond to the location for taller bumps to be provided on the substrate. In some examples, the locations of the taller bumps are defined based on the expected warpage of the substrate and/or an interfacing substrate to be coupled to the substrate being fabricated. In some examples, the locations of the taller bumps follow a pattern and/or any other suitable arrangement or distribution across the surface of the substrate as described in connection with FIG. 10. In some examples, the locations of the taller bumps are defined randomly and/or pseudo-randomly. At block 1106, additional metal is deposited on to the first metal in the uncovered first subset of openings to define taller bases for a first subset of bumps (e.g., taller bumps). In some examples, the additional metal deposited at block 1106 corresponds to the additional metal 513 and/or the metal plating 704 in FIGS. 5-7.

At block 1108, the upper photoresist layer is removed to uncover the first metal in the second subset of openings in the solder resist. In some examples, the first metal in the second openings corresponds to or defines shorter bases for a second subset of bumps (e.g., shorter or regular bumps). In some examples, the upper photoresist layer removed at block 1108 corresponds to the single photoresist layer 506 shown and described in connection with FIG. 5. In some examples, the upper photoresist layer removed at block 1108 corresponds to the second photoresist layer 709 in FIG. 7. At block 1110, solder is deposited on the bases for both the first subset of bumps (e.g., the taller bumps) and the second subset of bumps (e.g., the shorter bumps). In some examples, the solder deposited at block 1110 corresponds to the micro balls 507, 508, 601, 606, the solder paste 607, and/or the thin solder layer 715 described above in connection with FIGS. 5-7.

At block 1112, another photoresist layer is deposited and patterned to cover the taller bases associated with the first subset of bumps and uncover or expose the shorter bases associated with the second subset of bumps. In some examples, the additional photoresist layer deposited and patterned at block 1112 corresponds to the third photoresist 719 described above in connection with FIG. 7. At block 1114, additional solder is deposited on shorter bases associated with the second subset of bumps. In some examples, the additional solder at block 1112 corresponds to the additional solder 720 in FIG. 7. At block 1116, the remaining photoresist layer(s) are removed. In some examples, the photoresist layer(s) removed at block 1116 corresponds to the first and third photoresist layers 706, 719 in FIG. 7. In some examples, blocks 1112-1116 may be omitted such as when the example method of FIG. 11 is being implemented to fabricate the substrates of FIGS. 5 and 6. That is, in some examples, blocks 1112-1116 are specific to the method of manufacturing the substrate shown in FIG. 7. Thereafter, the example method of FIG. 11 ends and the substrate including taller bumps and shorter bumps can be used for further processing.

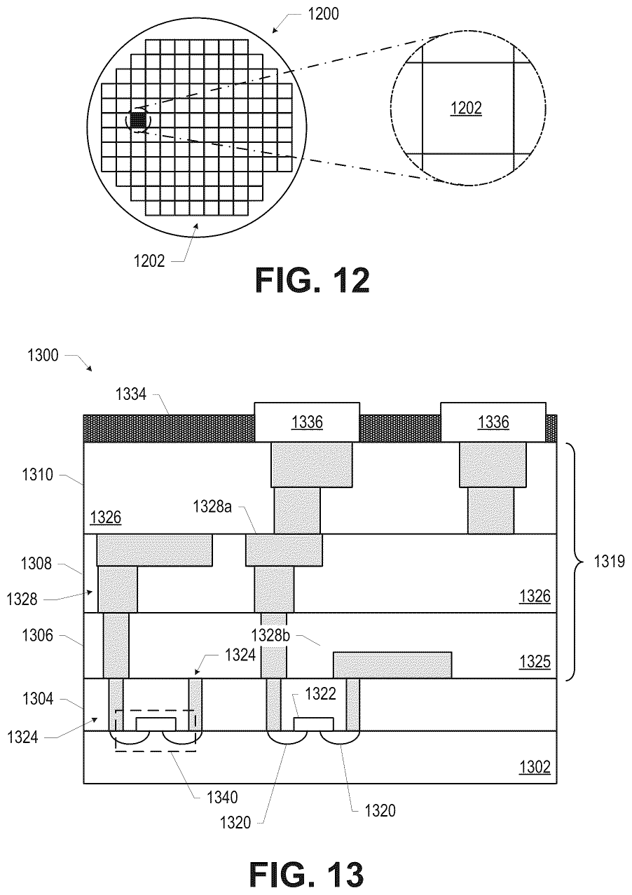

The example IC package 100 disclosed herein may be included in any suitable electronic component. FIGS. 12-15 illustrate various examples of apparatus that may include or be included in the IC package 100 disclosed herein.

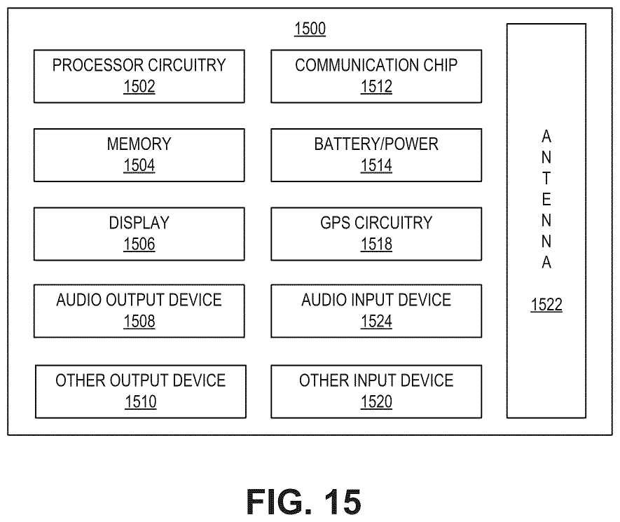

FIG. 12 is a top view of a wafer 1200 and dies 1202 that may be included in the IC package 100 of FIG. 1 (e.g., as any suitable ones of the dies 106, 108). The wafer 1200 may be composed of semiconductor material and may include one or more dies 1202 having circuitry. Each of the dies 1202 may be a repeating unit of a semiconductor product. After the fabrication of the semiconductor product is complete, the wafer 1200 may undergo a singulation process in which the dies 1202 are separated from one another to provide discrete “chips.” The die 1202 may include one or more transistors (e.g., some of the transistors 1340 of FIG. 13, discussed below), supporting circuitry to route electrical signals to the transistors, passive components (e.g., traces, resistors, capacitors, inductors, and/or other circuitry), and/or any other components. In some examples, the die 1202 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1202. For example, a memory array formed by multiple memory circuits may be formed on a same die 1202 as programmable circuitry (e.g., the processor circuitry 1502 of FIG. 15) or other logic circuitry. Such memory may store information for use by the programmable circuitry. The example IC package 100 disclosed herein may be manufactured using a die-to-wafer assembly technique in which some dies 106, 108 are attached to a wafer 1900 that include others of the dies 106, 108, and the wafer 1200 is subsequently singulated.

FIG. 13 is a cross-sectional side view of an IC device 1300 that may be included in the example IC package 100 (e.g., in any one of the dies 106, 108). One or more of the IC devices 1300 may be included in one or more dies 1202 (FIG. 12). The IC device 1300 may be formed on a die substrate 1302 (e.g., the wafer 1200 of FIG. 12) and may be included in a die (e.g., the die 1202 of FIG. 12). The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some examples, the die substrate 1302 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an IC device 1300 may be used. The die substrate 1302 may be part of a singulated die (e.g., the dies 1202 of FIG. 12) or a wafer (e.g., the wafer 1200 of FIG. 12).

The IC device 1300 may include one or more device layers 1304 disposed on or above the die substrate 1302. The device layer 1304 may include features of one or more transistors 1340 (e.g., metal oxide semiconductor field-effect transistors (MOSFETs)) formed on the die substrate 1302. The device layer 1304 may include, for example, one or more source and/or drain (S/D) regions 1320, a gate 1322 to control current flow between the S/D regions 1320, and one or more S/D contacts 1324 to route electrical signals to/from the S/D regions 1320. The transistors 1340 may include additional features not depicted for the sake of clarity, such as device isolation regions, gate contacts, and the like. The transistors 1340 are not limited to the type and configuration depicted in FIG. 13 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1340 may include a gate 1322 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1340 along the source-channel-drain direction, the gate electrode may consist of a U-shaped structure that includes a bottom portion substantially parallel to the surface of the die substrate 1302 and two sidewall portions that are substantially perpendicular to the top surface of the die substrate 1302. In other examples, at least one of the metal layers that form the gate electrode may simply be a planar layer that is substantially parallel to the top surface of the die substrate 1302 and does not include sidewall portions substantially perpendicular to the top surface of the die substrate 1302. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used: for instance, two pairs, three pairs, or four pairs of sidewall spacers may be formed on opposing sides of the gate stack.

The S/D regions 1320 may be formed within the die substrate 1302 adjacent to the gate 1322 of each transistor 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be carried out to fill the recesses with material that is used to fabricate the S/D regions 1320. In some implementations, the S/D regions 1320 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1320 may be formed using one or more alternate semiconductor materials such as germanium or a group III-V material or alloy. In further examples, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 2028 of the interconnect layers 1306-1310. The one or more interconnect layers 1306-1310 may form a metallization stack (also referred to as an “ILD stack”) 1319 of the IC device 1300.

The interconnect structures 1328 may be arranged within the interconnect layers 1306-1310 to route electrical signals according to a wide variety of designs (in particular, the arrangement is not limited to the particular configuration of interconnect structures 1328 depicted in FIG. 13). Although a particular number of interconnect layers 1306-1310 is depicted in FIG. 13, examples of the present disclosure include IC devices having more or fewer interconnect layers than depicted.

In some examples, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page from the perspective of FIG. 13. The vias 1328b may be arranged to route electrical signals in a direction of a plane that is substantially perpendicular to the surface of the die substrate 1302 upon which the device layer 1304 is formed. In some examples, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some examples, the dielectric material 2026 disposed between the interconnect structures 1328 in different ones of the interconnect layers 1306-1310 may have different compositions; in other examples, the composition of the dielectric material 1326 between different interconnect layers 1306-1310 may be the same.

A first interconnect layer 1306 (referred to as Metal 1 or “M1”) may be formed directly on the device layer 1304. In some examples, the first interconnect layer 1306 may include lines 1328a and/or vias 1328b, as shown. The lines 1328a of the first interconnect layer 1306 may be coupled with contacts (e.g., the S/D contacts 1324) of the device layer 1304.

A second interconnect layer 1308 (referred to as Metal 2 or “M2”) may be formed directly on the first interconnect layer 1306. In some examples, the second interconnect layer 1308 may include vias 1328b to couple the lines 1328a of the second interconnect layer 1308 with the lines 1328a of the first interconnect layer 1306. Although the lines 1328a and the vias 1328b are structurally delineated with a line within each interconnect layer (e.g., within the second interconnect layer 1308) for the sake of clarity, the lines 1328a and the vias 1328b may be structurally and/or materially contiguous (e.g., simultaneously filled during a dual-damascene process) in some examples.

A third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some examples, the interconnect layers that are “higher up” in the metallization stack 1319 in the IC device 1300 (i.e., further away from the device layer 1304) may be thicker.

The IC device 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to other external devices. For example, solder bonds may be formed on the one or more conductive contacts 1336 to mechanically and/or electrically couple a chip including the IC device 1300 with another component (e.g., a circuit board). The IC device 1300 may include additional or alternate structures to route the electrical signals from the interconnect layers 1306-1310; for example, the conductive contacts 1336 may include other analogous features (e.g., posts) that route the electrical signals to external components.

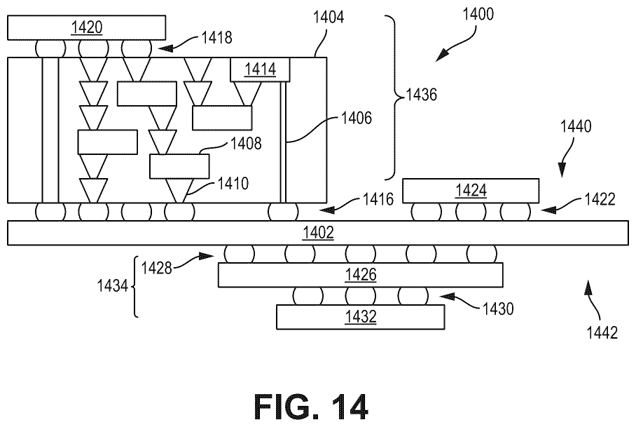

FIG. 14 is a cross-sectional side view of an IC device assembly 1400 that may include the IC package 100 disclosed herein. In some examples, the IC device assembly corresponds to the IC package 100. The IC device assembly 1400 includes a number of components disposed on a circuit board 1402 (which may be, for example, a motherboard). The IC device assembly 1400 includes components disposed on a first face 1440 of the circuit board 1402 and an opposing second face 1442 of the circuit board 1402; generally, components may be disposed on one or both faces 1440 and 1442. Any of the IC packages discussed below with reference to the IC device assembly 1400 may take the form of the example IC package 100 of FIG. 1.

In some examples, the circuit board 1402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1402. In other examples, the circuit board 1402 may be a non-PCB substrate. In some examples, the circuit board 1402 may be, for example, the circuit board 102 of FIG. 1.

The IC device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), male and female portions of a socket, an adhesive, an underfill material, and/or any other suitable electrical and/or mechanical coupling structure.

The package-on-interposer structure 1436 may include an IC package 1420 coupled to an interposer 1404 by coupling components 1418. The coupling components 1418 may take any suitable form for the application, such as the forms discussed above with reference to the coupling components 1416. Although a single IC package 1420 is shown in FIG. 14, multiple IC packages may be coupled to the interposer 1404; indeed, additional interposers may be coupled to the interposer 1404. The interposer 1404 may provide an intervening substrate used to bridge the circuit board 1402 and the IC package 1420. The IC package 1420 may be or include, for example, a die (the die 1202 of FIG. 12), an IC device (e.g., the IC device 1300 of FIG. 13), or any other suitable component. Generally, the interposer 1404 may spread a connection to a wider pitch or reroute a connection to a different connection. For example, the interposer 1404 may couple the IC package 1420 (e.g., a die) to a set of BGA conductive contacts of the coupling components 1416 for coupling to the circuit board 1402. In the example illustrated in FIG. 14, the IC package 1420 and the circuit board 1402 are attached to opposing sides of the interposer 1404; in other examples, the IC package 1420 and the circuit board 1402 may be attached to a same side of the interposer 1404. In some examples, three or more components may be interconnected by way of the interposer 1404.

In some examples, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through-silicon vias (TSVs) 1406. The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The IC device assembly 1400 may include an IC package 1424 coupled to the first face 1440 of the circuit board 1402 by coupling components 1422. The coupling components 1422 may take the form of any of the examples discussed above with reference to the coupling components 1416, and the IC package 1424 may take the form of any of the examples discussed above with reference to the IC package 1420.

The IC device assembly 1400 illustrated in FIG. 14 includes a package-on-package structure 1434 coupled to the second face 1442 of the circuit board 1402 by coupling components 1428. The package-on-package structure 1434 may include a first IC package 1426 and a second IC package 1432 coupled together by coupling components 1430 such that the first IC package 1426 is disposed between the circuit board 1402 and the second IC package 1432. The coupling components 1428, 1430 may take the form of any of the examples of the coupling components 1416 discussed above, and the IC packages 1426, 1432 may take the form of any of the examples of the IC package 1420 discussed above. The package-on-package structure 1434 may be configured in accordance with any of the package-on-package structures known in the art.

FIG. 15 is a block diagram of an example electrical device 1500 that may include one or more of the example IC packages 100 of FIG. 1. For example, any suitable ones of the components of the electrical device 1500 may include one or more of the device assemblies 1400, IC devices 1300, or dies 1202 disclosed herein, and may be arranged in the example IC package 100. A number of components are illustrated in FIG. 15 as included in the electrical device 1500, but any one or more of these components may be omitted or duplicated, as suitable for the application. In some examples, some or all of the components included in the electrical device 1500 may be attached to one or more motherboards. In some examples, some or all of these components are fabricated onto a single system-on-a-chip (SoC) die.

Additionally, in various examples, the electrical device 1500 may not include one or more of the components illustrated in FIG. 15, but the electrical device 1500 may include interface circuitry for coupling to the one or more components. For example, the electrical device 1500 may not include a display 1506, but may include display interface circuitry (e.g., a connector and driver circuitry) to which a display 1506 may be coupled. In another set of examples, the electrical device 1500 may not include an audio input device 1524 (e.g., microphone) or an audio output device 1508 (e.g., a speaker, a headset, earbuds, etc.), but may include audio input or output device interface circuitry (e.g., connectors and supporting circuitry) to which an audio input device 1524 or audio output device 1508 may be coupled.

The electrical device 1500 may include programmable circuitry 1502 (e.g., one or more processing devices). The programmable circuitry 1502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1500 may include a memory 1504, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1504 may include memory that shares a die with the programmable circuitry 1502. This memory may be used as cache memory and may include embedded dynamic random access memory (eDRAM) or spin transfer torque magnetic random access memory (STT-MRAM).

In some examples, the electrical device 1500 may include a communication chip 1512 (e.g., one or more communication chips). For example, the communication chip 1512 may be configured for managing wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802, 16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1512 may operate in accordance with other wireless protocols in other examples. The electrical device 1500 may include an antenna 1522 to facilitate wireless communications and/or to receive other wireless communications (such as AM or FM radio transmissions).

In some examples, the communication chip 1512 may manage wired communications, such as electrical, optical, or any other suitable communication protocols (e.g., the Ethernet). As noted above, the communication chip 1512 may include multiple communication chips. For instance, a first communication chip 1512 may be dedicated to shorter-range wireless communications such as Wi-Fi or Bluetooth, and a second communication chip 1512 may be dedicated to longer-range wireless communications such as global positioning system (GPS), EDGE, GPRS, CDMA, WIMAX, LTE, EV-DO, or others. In some examples, a first communication chip 1512 may be dedicated to wireless communications, and a second communication chip 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display 1506 (or corresponding interface circuitry, as discussed above). The display 1506 may include any visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any device that generates an audible indicator, such as speakers, headsets, or earbuds.

The electrical device 1500 may include an audio input device 1524 (or corresponding interface circuitry, as discussed above). The audio input device 1524 may include any device that generates a signal representative of a sound, such as microphones, microphone arrays, or digital instruments (e.g., instruments having a musical instrument digital interface (MIDI) output).

The electrical device 1500 may include GPS circuitry 1518. The GPS circuitry 1518 may be in communication with a satellite-based system and may receive a location of the electrical device 1500, as known in the art.

The electrical device 1500 may include any other output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include any other input device 1520 (or corresponding interface circuitry, as discussed above). Examples of the other input device 1520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1500 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A. (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A. (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that reduce solder bump bridging between two substrates by implementing substrates (e.g., dies and/or package substrates supporting dies) with bumps having bases with different heights and different amounts of solder. The bumps with taller bases and less solder serve as pillars that provide mechanical support to resist the compression of two substrates to be coupled during a TCB process, thereby reducing the likelihood of the solder on the bumps with shorter (regular) bases from being crushed and forced laterally to produce in solder bridging. Further, the bridging of solder on the taller bases is less of a concern because less solder is provided on such bases. Disclosed systems, methods, apparatus, and articles of manufacture improve the operation of an IC package by reducing short circuiting caused by solder bump bridging. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture to reduce solder bump bridging between two substrates are disclosed herein. Further examples and combinations thereof include the following:
Example 1 includes an apparatus comprising a first substrate including a first bump and a second bump spaced apart from the first bump, the first bump including a first base, the second bump including a second base, and a second substrate including a third bump and a fourth bump spaced apart from the third bump, the third bump including a third base, the fourth bump including a fourth base, the first base electrically coupled to the third base by first solder, the second base electrically coupled to the fourth base by second solder, the first base having a first height and the second base having a second height, the first height greater than the second height.
Example 2 includes the apparatus as defined in example 1, wherein at least one of the first, second, third or fourth base includes copper.
Example 3 includes the apparatus as defined in example 1, wherein the solder includes tin.
Example 4 includes the apparatus as defined in example 1, wherein the first solder has a first volume and the second solder has a second volume, the first volume less than the second volume.
Example 5 includes the apparatus as defined in example 1, wherein the third base has a third height and the fourth base has a fourth height, the third height greater than the fourth height.
Example 6 includes the apparatus as defined in example 1, wherein the first substrate includes a first plurality of bumps and a second plurality of bumps, the first plurality of bumps including the first bump, the second plurality of bumps including the second bump, the first plurality of bumps having bases with the first height, the second plurality of bumps having bases with the second height, the first plurality of bumps distributed across a first area of the substrate, the second plurality of bumps distributed across a second area of the substrate, the second area overlapping the first area.
Example 7 includes the apparatus as defined in example 6, wherein the first bump is spaced apart from the second bump by a first distance, the first plurality of bumps including a fifth bump spaced apart from the first bump by a second distance, the second distance greater than the first distance.
Example 8 includes the apparatus as defined in example 6, wherein the first area is smaller than the second area, and the first area is entirely contained within the second area.
Example 9 includes the apparatus as defined in example 1, wherein the first base has a first cross-sectional profile shape, and the second base has a second cross-sectional profile shape different than the first cross-sectional profile shape.
Example 10 includes the apparatus as defined in example 1, wherein the first base includes a first diameter, and the second base includes a second diameter, the first diameter approximately equal to the second diameter.
Example 11 includes the apparatus as defined in example 1, wherein the first solder extends a first distance between the first bump and the third bump, and the second solder extends a second distance between the second bump and the fourth bump, the first distance less than the second distance.
Example 12 includes the apparatus as defined in example 1, wherein the first substrate corresponds to either a semiconductor die or a package substrate, and the second substrate corresponds to the other of the semiconductor die or the package substrate.
Example 13 includes the apparatus as defined in example 1, wherein a height difference between the first height and the second height is at least 10 microns.
Example 14 includes an apparatus comprising a first substrate including first contacts, and a second substrate including second contacts, the first and second substrates corresponding to different ones of a semiconductor die and a package substrate supporting the semiconductor die, the first contacts including first surfaces to face towards the second contacts, the second contacts including second surfaces to face towards the first contacts, the second contacts electrically coupled to respective ones of the first contacts by solder disposed between corresponding pairs of the first and second surfaces, a first one of the first surfaces being closer to the second substrate than a second one of the first surfaces is to the second substrate.
Example 15 includes the apparatus as defined in example 14, wherein the first contacts include bases defining the first surfaces, a first one of the bases protruding farther from a solder resist layer of the first substrate than a second one of the bases protrudes from the solder resist layer.
Example 16 includes the apparatus as defined in example 14, wherein the solder electrically coupled to the first one of the first surfaces has a first volume, and the solder electrically coupled to the second one of the first surfaces has a second volume, the second volume being greater than the first volume.
Example 17 includes the apparatus as defined in example 14, wherein ones of a first plurality of the first surfaces are closer to the second substrate than ones of a second plurality of the first surfaces are to the second substrate, first ones of the first contacts associated with the first plurality being interspersed between second ones of the second contacts associated with the second plurality.
Example 18 includes the apparatus as defined in example 14, wherein the first one of the first surfaces is closer to a center of the first substrate than the second one of the first surfaces is to the center of the first substrate.
Example 19 includes the apparatus as defined in example 14, wherein the first contacts include bases extending through openings in a solder resist layer of the first substrate, distal faces of the bases corresponding to the first surfaces of the first contacts, a first one of the bases extending farther through a corresponding first one of the openings than a second one of the bases extends through a corresponding second one of the openings.
Example 20 includes a method of manufacturing a substrate for an integrated circuitry package, the method comprising depositing first metal to define an array of bases for contacts on the substrate, depositing second metal on a first subset of the bases to increase a thickness of the first subset of the bases relative to a second subset of the bases, and depositing solder on the first subset of the bases and the second subset of the bases.
Example 21 includes the method as defined in example 20, wherein a greater amount of the solder is deposited onto ones of the second subset of the bases than is deposited onto ones of the first subset of the bases.
Example 22 includes the method as defined in example 20, further including depositing a first photoresist over the first metal, lithographically patterning the first photoresist to define first openings extending therethrough, the first metal deposited into the first openings, depositing a second photoresist over the first photoresist, and lithographically patterning the second photoresist to define second openings extending therethrough, the second openings aligned with a first subset of the first openings, the first subset of the first openings corresponding to the first subset of the bases, the second metal deposited onto the first metal through the second openings.
Example 23 includes the method as defined in example 22, further including depositing a first layer of the solder onto the second metal, depositing a third photoresist over the first layer of the solder, lithographically patterning the third photoresist layer to define third openings extending therethrough, the third openings aligned with the second subset of the bases, and depositing a second layer of the solder into the third openings.
Example 24 includes the method as defined in example 23, further including removing the second photoresist before depositing the first layer of the solder such that the first layer of the solder is deposited onto all of the bases and the second layer of the solder is deposited onto the first layer of the solder.
Example 25 includes the method as defined in example 23, further including removing the second photoresist after depositing the first layer of the solder such that the first layer of the solder is deposited onto the first subset of the bases without being deposited on the second subset of the bases, the second layer being thicker than the first layer.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An apparatus comprising:
a first substrate including a first bump and a second bump spaced apart from the first bump, the first bump including a first base, the second bump including a second base; and
a second substrate including a third bump and a fourth bump spaced apart from the third bump, the third bump including a third base, the fourth bump including a fourth base, the first base electrically coupled to the third base by first solder, the second base electrically coupled to the fourth base by second solder, the first base having a first height and the second base having a second height, the first height greater than the second height.

2. The apparatus as defined in claim 1, wherein at least one of the first, second, third or fourth base includes copper.

3. The apparatus as defined in claim 1, wherein the solder includes tin.

4. The apparatus as defined in claim 1, wherein the first solder has a first volume and the second solder has a second volume, the first volume less than the second volume.

5. The apparatus as defined in claim 1, wherein the third base has a third height and the fourth base has a fourth height, the third height greater than the fourth height.

6. The apparatus as defined in claim 1, wherein the first substrate includes a first plurality of bumps and a second plurality of bumps, the first plurality of bumps including the first bump, the second plurality of bumps including the second bump, the first plurality of bumps having bases with the first height, the second plurality of bumps having bases with the second height, the first plurality of bumps distributed across a first area of the substrate, the second plurality of bumps distributed across a second area of the substrate, the second area overlapping the first area.

7. The apparatus as defined in claim 6, wherein the first bump is spaced apart from the second bump by a first distance, the first plurality of bumps including a fifth bump spaced apart from the first bump by a second distance, the second distance greater than the first distance.

8. The apparatus as defined in claim 6, wherein the first area is smaller than the second area, and the first area is entirely contained within the second area.

9. The apparatus as defined in claim 1, wherein the first base has a first cross-sectional profile shape, and the second base has a second cross-sectional profile shape different than the first cross-sectional profile shape.

10. The apparatus as defined in claim 1, wherein the first base includes a first diameter, and the second base includes a second diameter, the first diameter approximately equal to the second diameter.

11. The apparatus as defined in claim 1, wherein the first solder extends a first distance between the first bump and the third bump, and the second solder extends a second distance between the second bump and the fourth bump, the first distance less than the second distance.

12. The apparatus as defined in claim 1, wherein the first substrate corresponds to either a semiconductor die or a package substrate, and the second substrate corresponds to the other of the semiconductor die or the package substrate.

13. The apparatus as defined in claim 1, wherein a height difference between the first height and the second height is at least 10 microns.

14. An apparatus comprising:
a first substrate including first contacts; and
a second substrate including second contacts, the first and second substrates corresponding to different ones of a semiconductor die and a package substrate supporting the semiconductor die, the first contacts including first surfaces to face towards the second contacts, the second contacts including second surfaces to face towards the first contacts, the second contacts electrically coupled to respective ones of the first contacts by solder disposed between corresponding pairs of the first and second surfaces, a first one of the first surfaces being closer to the second substrate than a second one of the first surfaces is to the second substrate.

15. The apparatus as defined in claim 14, wherein the first contacts include bases defining the first surfaces, a first one of the bases protruding farther from a solder resist layer of the first substrate than a second one of the bases protrudes from the solder resist layer.

16. The apparatus as defined in claim 14, wherein the solder electrically coupled to the first one of the first surfaces has a first volume, and the solder electrically coupled to the second one of the first surfaces has a second volume, the second volume being greater than the first volume.

17. The apparatus as defined in claim 14, wherein ones of a first plurality of the first surfaces are closer to the second substrate than ones of a second plurality of the first surfaces are to the second substrate, first ones of the first contacts associated with the first plurality being interspersed between second ones of the second contacts associated with the second plurality.

18. The apparatus as defined in claim 14, wherein the first one of the first surfaces is closer to a center of the first substrate than the second one of the first surfaces is to the center of the first substrate.

19. The apparatus as defined in claim 14, wherein the first contacts include bases extending through openings in a solder resist layer of the first substrate, distal faces of the bases corresponding to the first surfaces of the first contacts, a first one of the bases extending farther through a corresponding first one of the openings than a second one of the bases extends through a corresponding second one of the openings.

20. A method of manufacturing a substrate for an integrated circuitry package, the method comprising:
depositing first metal to define an array of bases for contacts on the substrate;
depositing second metal on a first subset of the bases to increase a thickness of the first subset of the bases relative to a second subset of the bases; and
depositing solder on the first subset of the bases and the second subset of the bases.

21. The method as defined in claim 20, wherein a greater amount of the solder is deposited onto ones of the second subset of the bases than is deposited onto ones of the first subset of the bases.

22. The method as defined in claim 20, further including:
depositing a first photoresist over the first metal;
lithographically patterning the first photoresist to define first openings extending therethrough, the first metal deposited into the first openings;
depositing a second photoresist over the first photoresist; and
lithographically patterning the second photoresist to define second openings extending therethrough, the second openings aligned with a first subset of the first openings, the first subset of the first openings corresponding to the first subset of the bases, the second metal deposited onto the first metal through the second openings.

23. The method as defined in claim 22, further including:
depositing a first layer of the solder onto the second metal;
depositing a third photoresist over the first layer of the solder;
lithographically patterning the third photoresist layer to define third openings extending therethrough, the third openings aligned with the second subset of the bases; and
depositing a second layer of the solder into the third openings.

24. The method as defined in claim 23, further including removing the second photoresist before depositing the first layer of the solder such that the first layer of the solder is deposited onto all of the bases and the second layer of the solder is deposited onto the first layer of the solder.

25. The method as defined in claim 23, further including removing the second photoresist after depositing the first layer of the solder such that the first layer of the solder is deposited onto the first subset of the bases without being deposited on the second subset of the bases, the second layer being thicker than the first layer.
